(19) United States
(12) Patent Application Publication
(10) Pub. No.: US 2024/0215294 A1
(43) Pub. Date: Jun. 27, 2024

(54) DISPLAY DEVICE AND METHOD OF MANUFACTURING THE SAME

(71) Applicant: Japan Display Inc., Tokyo (JP)

(72) Inventors: Nobuto MANAGAKI, Tokyo (JP); Hayata AOKI, Tokyo (JP)

(73) Assignee: Japan Display Inc., Tokyo (JP)

(21) Appl. No.: 18/391,684

(22) Filed: Dec. 21, 2023

(30) Foreign Application Priority Data
Dec. 23, 2022 (JP) 2022-206916

(51) Int. Cl. H10K 50/18; H10K 59/35; H10K 71/10; H10K 101/40

(52) U.S. Cl. CPC H10K 50/181; H10K 59/35; H10K 71/10; H10K 2101/40

(57) ABSTRACT

According to one embodiment, a display device includes an anode, a cathode opposing the anode and an organic layer located between the anode and the cathode, and the organic layer includes a hole injection layer, a hole transport layer, an electron blocking layer, a light emitting layer, a hole blocking layer, an electron transport layer, and an electron injection layer, and at least one of the electron blocking layer and the hole blocking layer has a resistance of 10% or more and 30% or less in a thickness direction when a total resistance between the anode and the cathode is set to 100%.

### CROSS-REFERENCE TO RELATED APPLICATIONS

This application is based upon and claims the benefit of priority from Japanese Patent Application No. 2022-206916, filed Dec. 23, 2022, the entire contents of which are incorporated herein by reference.

### FIELD

Embodiments described herein relate generally to a display device and a method of manufacturing the display device.

### BACKGROUND

In recent years, display devices in which an organic light emitting diode (OLED) is applied as a display element have been put to practical use. Such a display device comprises an anode, a cathode opposing the anode and an organic layer located between the anode and the cathode. The organic layer includes functional layers such as a hole transport layer and an electron transport layer, in addition to a light emitting layer.

In such display devices, there is a demand to improve the light emission properties.

### BRIEF DESCRIPTION OF THE DRAWINGS

FIG. 1 is a perspective view showing a display device DSP according to an embodiment.

FIG. 2 is a diagram illustrating an example of layout of pixels PX in a display area DA shown in FIG. 1.

FIG. 3 is a diagram showing an example of the configuration of each pixel shown in FIG. 2.

FIG. 4 is a diagram illustrating an example of a method of manufacturing display elements 201, 202 and 203 shown in FIG. 3.

FIG. 5 is a diagram showing an example of an energy band in the display element 201.

FIG. 6 is a diagram showing an example of a relationship between applied voltage and current density in the display element 201.

FIG. 7 is a diagram showing the change in luminescence over elapsed time in the display element 201.

FIG. 8 is a diagram showing an example of a relationship between applied voltage and current density in the display element 201.

FIG. 9 is a diagram showing the change in luminescence over elapsed time in the display element 201.

FIG. 10 is a diagram showing an example of a relationship between applied voltage and current density in the display element 201.

FIG. 11A is a diagram showing the change in luminescence over elapsed time in the display element 201.

FIG. 11B is a diagram illustrating localization of current paths in a light emitting layer.

FIG. 12 is a diagram showing an example of a relationship between applied voltage and current density in the display element 201.

FIG. 13 is a diagram showing the change in luminescence over elapsed time in the display element 201.

FIG. 14 is a diagram showing an example of a relationship between applied voltage and current density in the display element 201.

FIG. 15 is a diagram showing the change in luminescence over elapsed time in the display element 201.

### DETAILED DESCRIPTION

In general, according to one embodiment, a display device comprising, an anode, a cathode opposing the anode, and an organic layer located between the anode and the cathode, wherein the organic layer includes a hole injection layer, a hole transport layer, an electron blocking layer, a light emitting layer, a hole blocking layer, an electron transport layer, and an electron injection layer, and at least one of the electron blocking layer and the hole blocking layer has a resistance of 10% or more and 30% or less in a thickness direction when a total resistance between the anode and the cathode is set to 100%.

According to another embodiment, a method of manufacturing a display device, comprising, forming an anode, forming an organic layer on the anode, and forming a cathode on the organic layer, wherein the forming the organic layer includes forming a hole injection layer, forming a hole transport layer, forming an electron blocking layer, forming a light emitting layer, forming a hole blocking layer, forming an electron transport layer, and forming an electron injection layer, and at least one of the electron blocking layer and the hole blocking layer is formed to have a resistance of 10% or more and 30% or less in a thickness direction when a total resistance between the anode and the cathode is set to 100%.

Embodiments will be described hereinafter with reference to the accompanying drawings.

Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and an overlapping detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction X, a direction along the Y axis is referred to as a second direction Y and a direction along the Z axis is referred to as a third direction Z. Viewing the elements in parallel with the third direction Z is referred to as plan view.

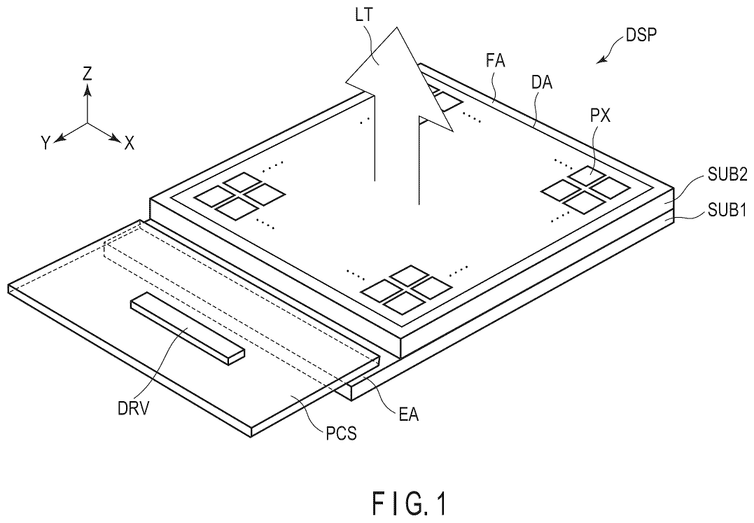

FIG. 1 is a perspective view showing a display device DSP according to an embodiment.

The display device DSP comprises substrates SUB1 and SUB2. The substrates SUB1 and SUB2 are each constituted by a glass substrate or a resin film as a base. The substrate SUB1 includes a display area DA which displays images and a peripheral area FA which surrounds the display area DA. The display area DA comprises a plurality of pixels PX arranged in a matrix along the first direction X and the second direction Y. The substrate SUB2 is overlaid on the display area DA. The peripheral area FA includes a terminal area EA for connecting a wiring board PCS and the like. The terminal area EA is located on an extending side of the substrate SUB1, which protrudes out further from the substrate SUB2.

The wiring board PCS contains a drive element DRV provided thereon, that outputs video signals and drive signals. The signals from the drive elements DRV are input to the pixels PX in the display area DA via the wiring board PCS. Each of the pixels PX emits light based on the video signals and various control signals. Emitted light LT from each pixel PX is transmitted through the substrate SUB2 and observed as an image.

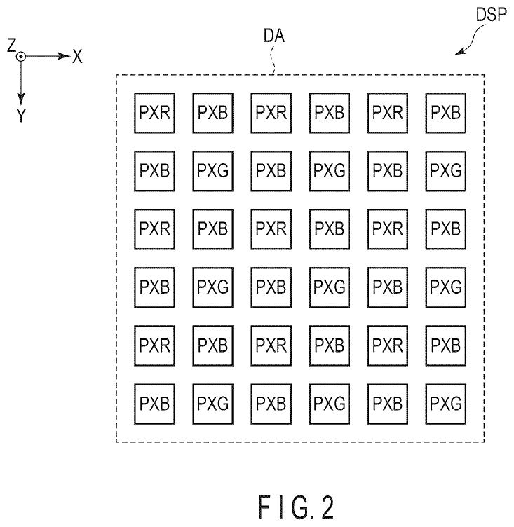

FIG. 2 is a diagram showing an example of layout of pixels PX in the display area DA shown in FIG. 1.

The display area DA includes, as the pixels PX, pixels PXB configured to emit blue light, pixels PXG configured to emit green light and pixels PXR configured to emit red light. The pixels PXR and the pixels PXB are arranged alternately along the first direction X and the second direction Y. The pixels PXG and the pixels PXB are arranged alternately along the first direction X and the second direction Y.

The layout of the pixels PX is not limited to that of the example shown in the figure.

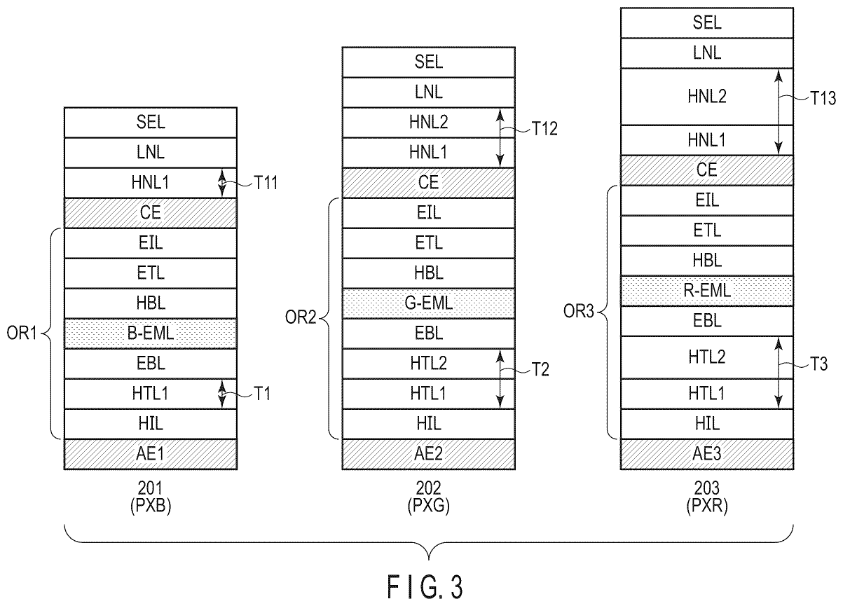

FIG. 3 is a diagram showing an example of the configuration of each of the pixels shown in FIG. 2.

The pixels PXB each comprise a display element 201, the pixels PXG comprise a display element 202 and the pixels PXR comprise a display element 203. The display elements 201, 202 and 203 are organic light emitting diodes (OLEDs) as light emitting elements and they may as well be referred to as organic EL elements.

The display element 201 comprises an anode AE1, an organic layer OR1 and a cathode CE. The cathode CE opposes the anode AE1. The organic layer OR1 is located between the anode AE1 and the cathode CE.

The organic layer OR1 comprises a hole injection layer HIL, a hole transport layer HTL1, an electron blocking layer EBL, a light emitting layer B-EML, a hole blocking layer HBL, an electron transport layer ETL and an electron injection layer EIL. The light emitting layer B-EML is configured to emit blue light.

The hole injection layer HIL, the hole transport layer HTL1 and the electron blocking layer EBL are stacked one on another in this order and are located between the anode AE1 and the light emitting layer B-EML. The hole transport layer HTL1 has a thickness T1. The electron blocking layer EBL is in contact with the light emitting layer B-EML.

The hole blocking layer HBL, the electron transport layer ETL and the electron injection layer EIL are stacked one on another in this order and are located between the light emitting layer B-EML and the cathode CE. The hole blocking layer HBL is in contact with the light emitting layer B-EML.

In the example illustrated, a high refractive index layer HNL1 is located on the cathode CE, a low refractive index layer LNL is located on the high refractive index layer HNL1, and a sealing layer SEL is located on the low refractive index layer LNL. The high refractive index layer HNL1 has a thickness T11. The refractive index of the high refractive index layer HNL1 is greater than that of the low refractive index layer LNL. The stacked body of the high refractive index layer HNL1 and the low refractive index layer LNL serves as an optical adjustment layer (cap layer) that can improve the extraction efficiency of light emitted from the light emitting layer B-EML. The sealing layer SEL has the role of sealing the display element 201.

For example, the hole injection layer HIL, the hole transport layer HTL1, the electron blocking layer EBL, the hole blocking layer HBL, the electron transport layer ETL, the electron injection layer EIL, the cathode CE, the high refractive index layer HNL1, the low refractive index layer LNL and the sealing layer SEL are common layers disposed over the display elements 201, 202 and 203. The light emitting layer B-EML is an individual layer disposed in the display element 201.

The display element 202 comprises an anode AE2, an organic layer OR2 and a cathode CE. The anode AE2 is spaced apart from the anode AE1. The cathode CE opposes the anode AE2. The organic layer OR2 is located between the anode AE2 and the cathode CE.

The organic layer OR2 comprises a hole injection layer HIL, a hole transport layer HTL1, a hole transport layer HTL2, an electron blocking layer EBL, a light emitting layer G-EML, a hole blocking layer HBL, an electron transport layer ETL and an electron injection layer EIL. The light emitting layer G-EML is configured to emit green light. The light emitting layer G-EML is an individual layer disposed in the display element 202.

The hole injection layer HIL, the hole transport layer HTL1, the hole transport layer HTL2 and the electron blocking layer EBL are stacked one on another in this order and are located between the anode AE2 and the light emitting layer G-EML. The hole transport layers HTL1 and HTL2 are formed of the same material, for example, and together have a thickness T2. The thickness T2 is greater than the thickness T1. The electron blocking layer EBL is in contact with the light emitting layer G-EML.

The hole blocking layer HBL, the electron transport layer ETL and the electron injection layer EIL are stacked one on another in this order and are located between the light emitting layer G-EML and the cathode CE. The hole blocking layer HBL is in contact with the light emitting layer G-EML.

In the example illustrated, the high refractive index layer HNL1 is located on the cathode CE, the high refractive index layer HNL2 is located on the high refractive index layer HNL1, the low refractive index layer LNL is located on the high refractive index layer HNL2, and the sealing layer SEL is located on the low refractive index layer LNL. The high refractive index layers HNL1 and HNL2 are formed of the same material, for example, and together have a thickness T12. The thickness T12 is greater than the thickness T11. The stacked body of the high refractive index layers HNL1 and HNL2 and the low refractive index layer LNL serves as an optical adjustment layer that can improve the extraction efficiency of light emitted from the light emitting layer G-EML. The sealing layer SEL has the role of sealing the display element 202.

The display element 203 comprises an anode AE3, an organic layer OR3 and a cathode CE. The anode AE3 is spaced apart from the anodes AE1 and AE2. The cathode CE opposes the anode AE3. The organic layer OR3 is located between the anode AE3 and the cathode CE.

The organic layer OR3 comprises a hole injection layer HIL, a hole transport layer HTL1, a hole transport layer HTL2, an electron blocking layer EBL, a light emitting layer R-EML, a hole blocking layer HBL, an electron transport layer ETL and an electron injection layer EIL. The light emitting layer R-EML is configured to emit red light. The light emitting layer R-EML is an individual layer disposed in the display element 203.

The hole injection layer HIL, the hole transport layer HTL1, the hole transport layer HTL2 and the electron blocking layer EBL are stacked one on another in this order and are located between the anode AE3 and the light emitting layer R-EML. The hole transport layers HTL1 and HTL2 together have a thickness T3. For example, the thickness T3 is greater than thickness T2. The electron blocking layer EBL is in contact with the light emitting layer R-EML.

The hole blocking layer HBL, the electron transport layer ETL and the electron injection layer EIL are stacked one on another in this order and are located between the light emitting layer R-EML and the cathode CE. The hole blocking layer HBL is in contact with the light emitting layer R-EML.

In the example illustrated, the high refractive index layer HNL1 is located on the cathode CE, the high refractive index layer HNL2 is located on the high refractive index layer HNL1, the low refractive index layer LNL is located on the high refractive index layer HNL2, and the sealing layer SEL is located on the low refractive index layer LNL. The high refractive index layers HNL1 and HNL2 are formed of, for example, the same material, and together have a thickness T13. The thickness T13 is greater than the thickness T12. The stacked body of the high refractive index layers HNL1 and HNL2 and the low refractive index layer LNL serves as an optical adjustment layer that can improve the extraction efficiency of light emitted from the light emitting layer R-EML. The sealing layer SEL has the role of sealing the display element 203.

The hole injection layer HIL injects holes from the anodes AE1, AE2 and AE3 to the hole transport layer, and the hole transport layers HTL1 and HTL2 transport the injected holes to the light emitting layer EML. The electron blocking layer EBL keeps the electrons injected from the cathode CE in the light emitting layer EML and prevents electrons from leaking out to the hole transport layers HTL1 and HTL2.

The electron injection layer EIL injects electrons from the cathode CE to the electron transport layer ETL, and the electron transport layer ETL transports the injected electrons to the light emitting layer EML. The hole blocking layer HBL keeps holes injected from the anode in the light emitting layer EML and prevents holes from leaking out to the electron transport layer ETL.

As for the hole injection layer HIL and the hole transport layers HTL1 and HTL2, when the hole injection barrier (the difference between the work function of the anode and the HOMO level of the material of the hole transport layer) from the anodes AE1, AE2 and AE3 is reduced, holes are allowed to flow smoothly.

As for the electron injection layer EIL and the electron transport layer ETL, when the electron injection barrier (the difference between the work function of the cathode and the LUMO level of the material of the electron transport layer) from the cathode CE is reduced, electrons are allowed to flow smoothly.

The light emission in the organic layers OR1, OR2 and OR3 is obtained in the following mechanism. That is, when the excitation energy of excitons generated by holes injected to the highest occupied molecular orbital (HOMO, generally measured as ionization potential) of the material of the emitting layer EML and electrons injected to the lowest unoccupied molecular orbital (LUMO, generally measured as electron affinity) relaxes, light is emitted.

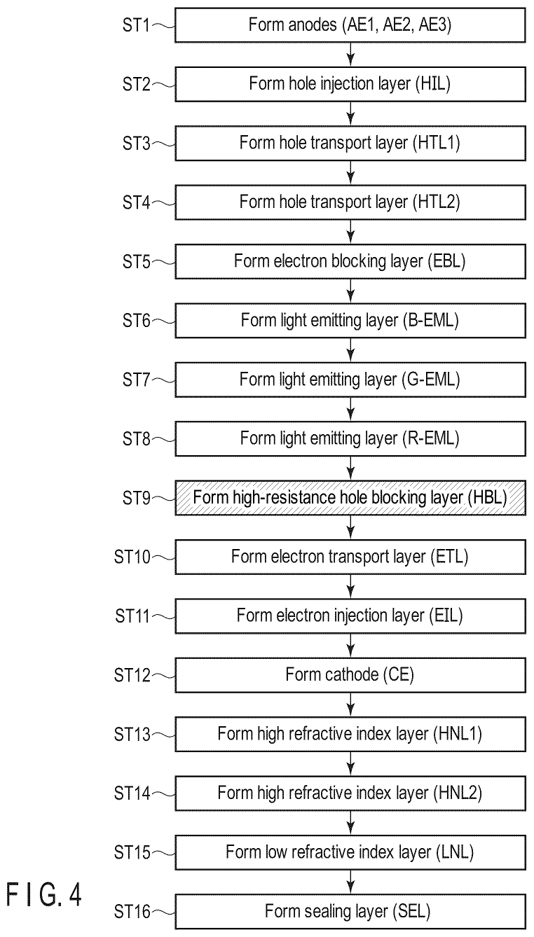

FIG. 4 is a diagram illustrating an example of a method of manufacturing the display elements 201, 202 and 203 shown in FIG. 3.

First, a conductive material is patterned to form the anodes AE1, AE2 and AE3 so as to be spaced apart from each other (step ST1). The anode AE1 is disposed in the pixel PXB, the anode AE2 is disposed in the pixel PXG and the anode AE3 is disposed in the pixel PXR. The anodes AE1, AE2 and AE3 are each a stacked body of, for example, a transparent electrode formed of indium tin oxide (ITO) or the like and a reflective electrode formed of silver (Ag) or the like.

After that, a rib is formed between each adjacent pair of the anodes AE1, AE2 and AE3. The rib may be an organic insulating film or an inorganic insulating film.

Next, a hole injection layer HIL is formed over the pixels PXB, PXG and PXR (step ST2). The hole injection layer HIL is disposed on the anodes AE1, AE2 and AE3.

Then, a hole transport layer HTL1 is formed over the pixels PXB, PXG and PXR (step ST3). The hole transport layer HTL1 is disposed on the hole injection layer HIL.

Subsequently, a hole transport layer HTL2 is formed in the pixels PXG and PXR (step ST4). The hole transport layer HTL2 is disposed on the hole transport layer HTL1 in each of the pixels PXG and PXR. At this time, as shown in FIG. 3, the hole transport layer HTL2 in the pixel PXR is formed to be thicker than the hole transport layer HTL2 in the pixel PXG.

Next, an electron blocking layer EBL is formed over the pixels PXB, PXG and PXR (step ST5). The electron blocking layer EBL is disposed on the hole transport layer HTL1 in the pixel PXB and also on the hole transport layer HTL2 in each of the pixels PXG and PXR.

Then, in the pixel PXB, a light emitting layer B-EML is formed (step ST6). The light emitting layer B-EML is formed by co-evaporation of a host material and a dopant that emits blue light. The light emitting layer B-EML is disposed on the electron blocking layer EBL and directly above the anode AE1.

Subsequently, in the pixel PXG, a light emitting layer G-EML is formed (step ST7). The light emitting layer G-EML is formed by co-evaporation of a host material and a dopant that emits green light. The light emitting layer G-EML is disposed on the electron blocking layer EBL and directly above the anode AE2.

Next, in the pixel PXR, a light emitting layer R-EML is formed (step ST8). The light emitting layer R-EML is formed by co-deposition of a host material and a dopant that emits red light. The light emitting layer R-EML is disposed on the electron blocking layer EBL and directly above the anode AE3.

Note that the order of formation of the light emitting layers B-EML, G-EML and R-EML is not limited to that of the example shown in FIG. 4. The chromaticity of red is: CIEx=0.635 and CIEy=0.315, that of green is: CIEx=0.227 and CIEy=0.717, and that of blue is CIEx=0.141 and CIEy=0.05. CIEx for red, CIEy for green and CIEy for blue serve an important role in the pixel design.

Next, a hole blocking layer HBL is formed over the pixels PXB, PXG and PXR (step ST9). The hole blocking layer HBL is disposed on the light emitting layer B-EML in the pixel PXB, on the light emitting layer G-EML in the pixel PXG, and on the light emitting layer R-EML in the pixel PXR.

Then, an electron transport layer ETL is formed over the pixels PXB, PXG and PXR (step ST10). The electron transport layer ETL is disposed on the hole blocking layer HBL.

Subsequently, an electron injection layer EIL is formed over the pixels PXB, PXG and PXR (step ST11). The electron injection layer EIL is disposed on the electron transport layer ETL.

After that, a cathode CE is formed over the pixels PXB, PXG and PXR (step ST12). The cathode CE is disposed on the electron injection layer EIL. The cathode CE is formed, for example, of an alloy of magnesium (Mg) and silver (Ag).

Next, a high refractive index layer HNL1 is formed over the pixels PXB, PXG and PXR (step ST13). The high refractive index layer HNL1 is disposed on the cathode CE.

Then, a high refractive index layer HNL2 is formed over the pixels PXG and PXR (step ST14). The high refractive index layer HNL2 is disposed on the high refractive index layer HNL1 in each of the pixels PXG and PXR. At this time, as shown in FIG. 3, the high refractive index layer HNL2 in the pixel PXR is formed to be thicker than the high refractive index layer HNL2 in the pixel PXG.

Subsequently, a low refractive index layer LNL is formed over the pixels PXB, PXG and PXR (step ST15). The low refractive index layer LNL is disposed on the high refractive index layer HNL1 in the pixel PXB and also on the high refractive index layer HNL2 in each of the pixels PXG and PXR.

After that, a sealing layer SEL is formed over the pixels PXB, PXG and PXR (step ST16). The sealing layer SEL is disposed on the low refractive index layer LNL.

At least the light emitting layers B-EML, G-EML and R-EML, the electron transport layer ETL and the electron injection layer EIL are co-deposition layers formed by depositing multiple materials at the same time.

It should be noted here that, in the above-described manufacturing process, at least one of the electron blocking layer EBL and the hole blocking layer HBL is formed so that the resistance thereof is in a range of 10% or more and 30% or less in the thickness direction when the total resistance between the anode AE1, AE2 and AE3 and the cathode CE is set to 100%. In at least one of the electron blocking layer EBL and the hole blocking layer HBL, the resistance value in the above-specified range is controlled by, for example, the mobility of the material, the potential barrier ΔE, the diode factor n, the capacitors, the number of carriers, film thickness and the like.

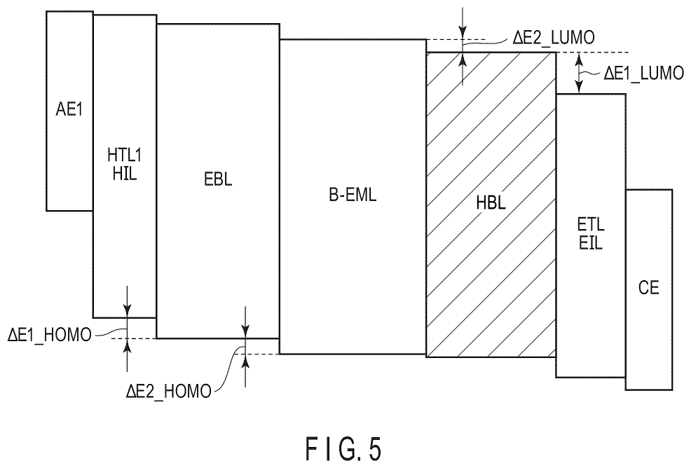

FIG. 5 is a diagram showing an example of an energy band in the display element 201.

In order to make hole injection and hole transport from the anode AE1 more effective, the hole injection material and the hole transport material are selected so that a staircase-shaped potential barrier is created in the interface of each layer from the Fermi level of the anode AE1 to the HOMO level of the light emitting layer B-EML. Such a staircase-shaped potential barrier is referred to as a staggered configuration.

Similarly, in order to make electron injection and transport from the cathode CE to be carried out more effective, the electron injection material and the electron transport material are selected so that a staircase-like potential barrier is created in the interface of each layer from the Fermi level of the cathode CE to the LUMO level of the light emitting layer B-EML. With the staircase-shaped potential barrier thus provided, it is possible to improve the properties of the carrier injection to the light emitting layer B-EML and enhances the light emission performance.

The potential barriers ΔE1_LUMO and ΔE2_LUMO in the figure correspond to the LUMO energy difference between each adjacent pair of the respective materials. Further, the potential barriers ΔE1_HOMO and ΔE2_HOMO in the figure correspond to the HOMO energy difference between each adjacent pair of the respective materials.

For example, the potential barrier between the electron injection layer EIL and the electron transport layer ETL, and the hole blocking layer HBL is referred to as ΔE1_LUMO. The potential barrier between the hole blocking layer HBL and the light emitting layer B-EML is referred to as ΔE2_LUMO.

The potential barrier between the hole injection layer HIL and the hole transport layer HTL1, and the electron blocking layer EBL is referred to as ΔE1_HOMO. The potential barrier between the electron blocking layer EBL and the light emitting layer B-EML is referred to as ΔE2_HOMO.

It is preferable that at least one of the potential barriers ΔE2_LUMO and ΔE2_HOMO should be 0.1 eV or more and 0.5 eV or less. When the potential barriers ΔE2_LUMO and ΔE2_HOMO are not particularly distinguished from each other, they are simply referred to as ΔE2. When ΔE2 is less than 0.1 eV (ΔE2<0.1 eV), carriers can easily flow from the light emitting layer B-EML. In order to place ΔE2 in the above-specified range, a material that can make the light emitting layer B-EML wide-gap (hereinafter referred to as “wide-gap material”) should be co-deposited when forming the light emitting layer B-EML. Alternatively, ΔE2 can be set within the above-specified range, for example, by selecting an appropriate material or by setting the film thickness appropriate.

It is preferable that at least one of the potential barrier ΔE1_LUMO and the potential barrier ΔE1_HOMO should be 0.3 eV or less. The potential barrier ΔE1_LUMO is assumed on that the work function of the cathode CE in contact with the electron injection layer EIL is 3.5 eV.

The inventors of the present embodiment have found that a longer life can be achieved by making the electron blocking layer EBL and the hole blocking layer HBL, which are in contact with the light emitting layer B-EML, highly resistive, in the display device 201.

A degradation test in which the current continues to flow from the initial state was carried out. Here, the luminance ratio between the initial state and the degraded state when the luminance of the initial state was decreased by 5% is defined as LT₉₅.

$$L {T}_{95} \approx exp ( ( q V / {n}^{′} KT ) - ( q V / nKT ) - ( {T}_{95} / τ ) )$$

$${T}_{95} / τ \approx q V / Δ nKT$$

where q represents the charge, V is for the voltage, n for the diode factor, K for the Boltzmann coefficient, T for the temperature and T95 is the time to reach LT₉₅. Note that (qV/nKT) is the output in the initial state, and (qV/n′KT) is the output after degradation tests.

The light emission and the recombination of the organic EL element is repeated with a single cycle of several microseconds. The cycle differs between the initial state of the organic EL element and after the degradation test due to partial breakdown of organic molecules. LT₉₅ represents the ratio of the luminance in the initial state compared to the luminance after the degradation test, and the qualitative characteristics are not lost if the light emission cycles between the initial state and after the degradation test are compared with each other. The voltage V depends on the resistance R. Therefore, based on the above-provided formulas, it is understood that the time T95 to reach LT₉₅ depends on the resistance value R.

First, the inventors prepared the display element 201 under different conditions in resistance value of the hole blocking layer HBL and carried out studies on its effects. Note that in this experiment, all organic layers, including the hole blocking layer HBL, were formed by point source deposition.

The point source deposition is a method in which a point-shaped deposition source containing the material to be deposited is placed to face the substrate, the deposition source is heated, and the vapor of the material emitted from the deposition source attaches to the substrate to form a thin film on the substrate. Note that in the case of forming a co-deposition layer by point source deposition, a plurality of point-shaped deposition sources containing materials different from each other are prepared, the deposition sources are heated while rotating the substrate, and the vapors of the materials emitted from the respective deposition sources mix with each other and attach to the substrate to form a co-deposition layer.

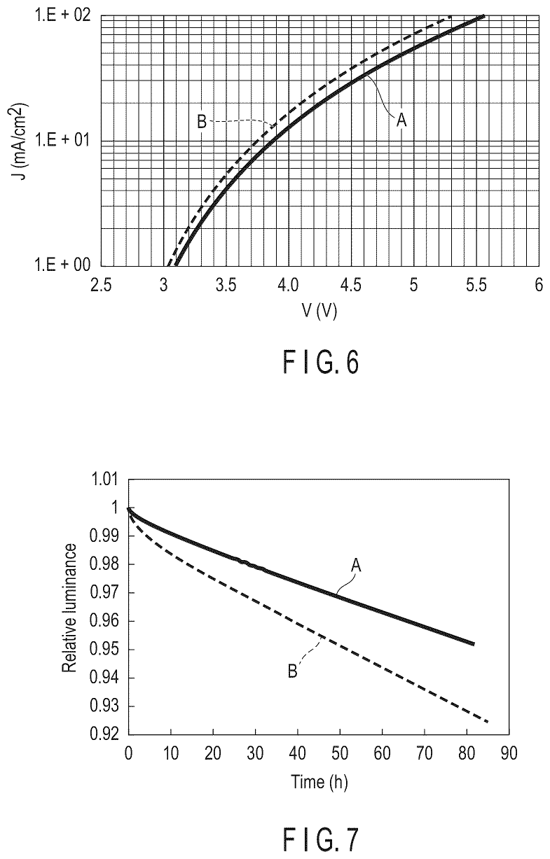

FIG. 6 is a diagram showing an example of the relationship between applied voltage and current density in the display element 201.

The horizontal axis of the figure indicates the applied voltage (V) whereas the vertical axis of the figure indicates the current density (mA/cm²).

A curve A in the figure shows the results of Embodiment 1 in which the hole blocking layer HBL is formed so as to have a resistance value of 10% or more when the total resistance between the anode ΔE1 and the cathode CE is 100%.

A curve B in the figure shows the results of Comparative Example 1 in which the hole blocking layer HBL is formed to have a resistance value of less than 10%.

For example, when the total resistance between the anode ΔE1 and the cathode CE was 309 kΩ/cm², in Embodiment 1, the hole blocking layer HBL had a resistance of 82 kΩ/cm² (equivalent to 26.5%), whereas in Comparative Example 1, the hole blocking layer HBL had a resistance of 26 kΩ/cm² (equivalent to 8%).

FIG. 7 is a diagram showing the change in luminescence over elapsed time in the display element 201. The results shown here correspond to the change over time in luminance obtained when a constant current is continuously applied to the display element 201.

The horizontal axis of the figure indicates the elapsed time, and the vertical axis of the figure indicates the relative luminance. The relative luminance is represented as a relative value when the luminance at an elapsed time of 0 hours is set to 1.

A curve A in the figure shows the results of Embodiment 1 (in which the hole blocking layer HBL has a resistance value of 10% or more).

A curve B in the figure shows the results of Comparative Example 1 (in which the hole blocking layer HBL has a resistance value of less than 10%).

As shown in FIG. 7, it has been confirmed that according to Embodiment 1, although the luminance decreases with time, a luminance higher than that of Comparative Example 1 can be obtained at any time. That is, it has been confirmed that, according to Embodiment 1, it is possible to achieve a longer life as compared to Comparative Example 1.

Next, the inventors prepared the display element 201 under different conditions in resistance value of the hole blocking layer HBL and the electron blocking layer EBL and carried out studies on its effects. Note that in this experiment, all organic layers including the hole blocking layer HBL and the electron blocking layer EBL were formed by point source deposition.

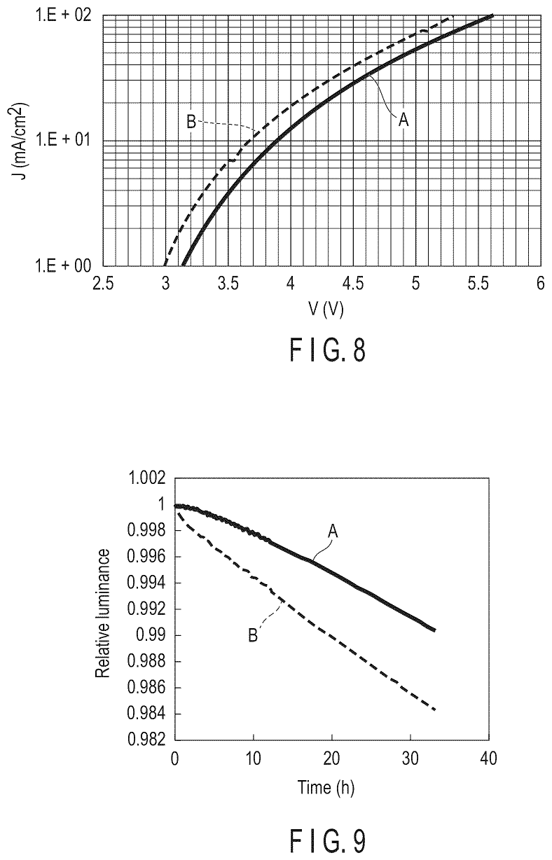

FIG. 8 is a diagram showing an example of the relationship between applied voltage and current density in the display device 201.

The horizontal axis of the figure indicates the applied voltage (V), whereas the vertical axis of the figure represents the current density (mA/cm²).

A curve A in the figure shows the results of Embodiment 2 in which the hole blocking layer HBL and the electron blocking layer EBL were formed so as to have a resistance value of 10% or more when the total resistance between the anode ΔE1 and the cathode CE is set to 100%.

A curve B in the figure shows the results of Comparative Example 2, in which the hole blocking layer HBL and the electron blocking layer EBL were formed to have a resistance value of less than 10%.

For example, when the total resistance between the anode ΔE1 and the cathode CE is 309 kΩ/cm², in Embodiment 2, the hole blocking layer HBL and the electron blocking layer EBL have a resistance of 82 kΩ/cm² (equivalent to 26.5%), while in Comparison 2, the hole blocking layer HBL and the electron blocking layer EBL have a resistance of 26 kΩ/cm² (equivalent to 8%).

FIG. 9 is a diagram showing the change in luminance over elapsed time in the display element 201.

The horizontal axis of the figure represents the elapsed time, whereas the vertical axis of the figure indicates the relative luminance. The relative luminance is represented as a relative value when the luminance at an elapsed time of 0 hours is set to 1.

A curve A in the figure shows the results of Embodiment 2 (in which the hole blocking layer HBL and the electron blocking layer EBL each have a resistance value of 10% or higher).

A curve B in the figure shows the results of Comparative Example 2 (in which the hole blocking layer HBL and the electron blocking layer EBL each have a resistance value of less than 10%).

As shown in FIG. 9, it has been confirmed that according to Embodiment 2, although the luminance decreases with time, a luminance higher than that of Comparative Example 2 can be obtained at any time. In other words, it has been confirmed that Embodiment 2 can achieve a longer life than that of Comparative Example 2.

Next, the inventors prepared the display element 201 under different conditions in resistance values of the hole blocking layer HBL and the electron blocking layer EBL and studied its effects. Note that in this experiment, all organic layers, including the hole blocking layer HBL and the electron blocking layer EBL, were formed by linear scan deposition.

The linear scan deposition is a method in which a linear deposition source containing the material to be deposited is placed to oppose a substrate, and the deposition source is heated while the deposition source and substrate are moved with relative to each other, and the vapor of the material emitted from the deposition source adheres to the substrate to form a thin film on the substrate. Note that in the case of forming a co-deposition layers by linear scan deposition, a plurality of linear deposition sources containing different materials are prepared, the deposition sources are heated while the substrate is moved relative to the fixed deposition source (or the deposition source is moved relative to the fixed substrate), and the vapors of the materials emitted from the respective deposition sources mix with each other and adhere to the substrate, to obtain a co-deposition layer. As compared to the point source deposition, which is the most widespread deposition process, the deposition process is a manufacturing method used in mass production for deposition on large substrates.

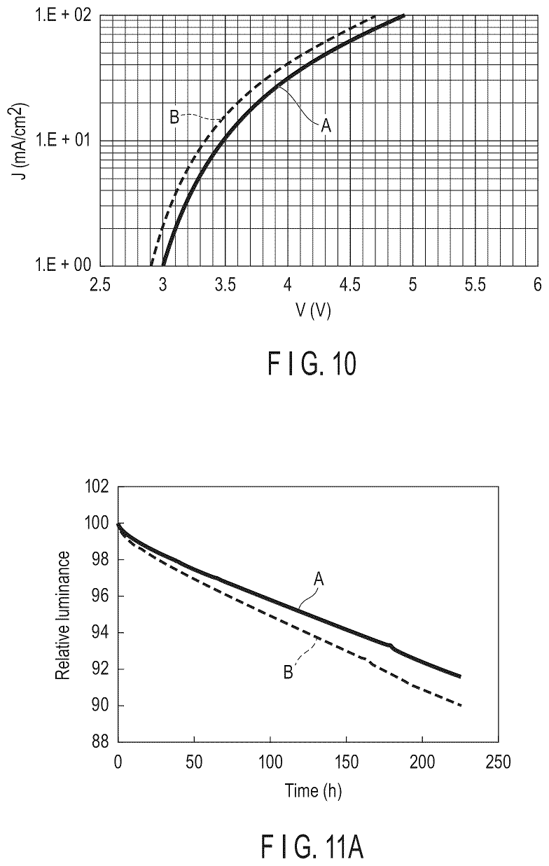

FIG. 10 is a diagram showing an example of the relationship between applied voltage and current density in the display element 201.

The horizontal axis of the figure indicates the applied voltage (V), and the vertical axis of the figure indicates the current density (mA/cm²).

A curve A in the figure shows the results of Embodiment 3, in which the hole blocking layer HBL and the electron blocking layer EBL are formed so as to have a resistance value of 10% or more when the total resistance between the anode ΔE1 and the cathode CE is set to 100%.

A curve B in the figure shows the results of Comparative Example 3, in which the hole blocking layer HBL and the electron blocking layer EBL were formed to have a resistance value of less than 10%.

For example, when the total resistance between the anode ΔE1 and the cathode CE is 309 kΩ/cm², in Embodiment 3, the hole blocking layer HBL and the electron blocking layer EBL each have a resistance of 82 kΩ/cm² (equivalent to 26.5%), whereas in Comparative Example 3, the hole blocking layer HBL and the electron blocking layer EBL each have a resistance value of 26 kg/cm² (equivalent to 8%).

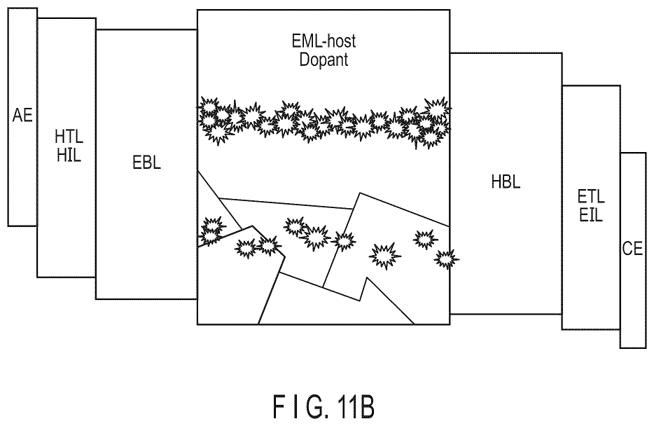

FIG. 11A is a diagram showing the change in luminance over elapsed time in the display element 201.

The horizontal axis of the figure indicates the elapsed time, and the vertical axis of the figure indicates the relative luminance. The relative luminance is represented as a relative value when the luminance at an elapsed time of 0 hours is set to 1.

A curve A in the figure shows the results of Embodiment 3 (in which the hole blocking layer HBL and the electron blocking layer EBL each have a resistance value of 10% or higher).

A curve B in the figure shows the results of Comparative Example 3 (in which the hole blocking layer HBL and the electron blocking layer EBL each have a resistance value of less than 10%).

As shown in FIG. 11A, it has been confirmed that according to Embodiment 3, although the luminance decreases with elapsed time, a luminance higher than that of Comparative Example 3 can be obtained at any time. In other words, it has been confirmed that Embodiment 3 can achieve a longer life than that of Comparative Example 3.

Here, the inventors found that the following causes of characteristics degradation occur in linear scan deposition, which is widely used as a production system, as compared to the point source deposition. In the linear scan deposition, a concentration gradient occurs in the material composition of the co-deposition layer, and current flows through a specific region as shown in FIG. 11B. As a result, the current is concentrated only in a part of the organic layer, which causes such a phenomenon of a significant decrease in lifetime. The effect by the decrease in lifetime is the most in blue color, and a decrease in lifetime of over 50% occurs. The red and green colors are next affected, and the lifetimes thereof decrease by about 10% to 5%.

The effect of the high resistivity of the hole blocking layer HBL and the electron blocking layer EBL described in Embodiment 3 indicates that it is effective in improvement in the reduction in lifetime specific to that of the linear scan deposition process, which is widely used as production device.

The effect of the high resistivity of the hole blocking layer HBL and the electron blocking layer EBL described in Embodiment 1 to Embodiment 2 indicates that it is effective in expansion of the lifetime in the point source deposition, which is most widely used. Further, the improvement effect is shown in devices having different production principles as well. The effect of expanding the lifetime has also been demonstrated in linear scan deposition, which became widely popular as a production device in Embodiment 3.

Based on these results of the studies, it has been confirmed that in the display device 201, by forming at least one of the hole blocking layer HBL and the electron blocking layer EBL to have a resistance value of 10% or more of the total resistance, the expansion of the lifetime can be achieved. It has been also confirmed that the expansion of the lifetime by increasing the resistances of the hole blocking layer HBL and the electron blocking layer EBL is an effective method for either one of the point source deposition and the linear scan deposition.

When at least one of the hole blocking layer HBL and the electron blocking layer EBL is made to have a high resistance, the effect of long life can be obtained, but the effect of improvement in lifetime tends to saturate as the resistance value increases.

Here, the inventors prepared the display element 201 under the condition that the resistance of the hole blocking layer HBL was further increased (the resistance value of the electron blocking layer EBL remained unchanged), and carried out studies on its effects. Note that in this experiment, all organic layers, including the hole blocking layer HBL, were formed by point source deposition.

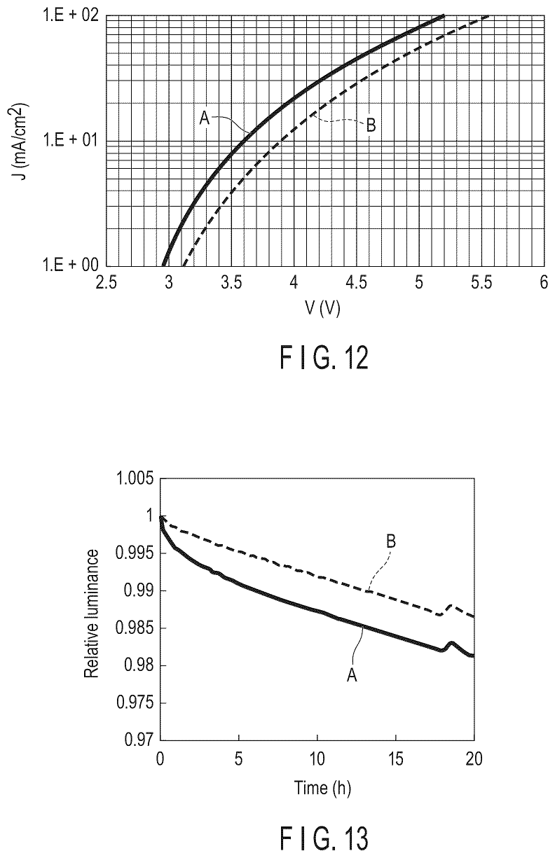

FIG. 12 is a diagram showing an example of the relationship between applied voltage and current density in the display element 201.

A curve A in the figure shows the results of Embodiment 4, in which the hole blocking layer HBL is formed to have a resistance of 30% or less when the total resistance between the anode ΔE1 and the cathode CE is set to 100%.

A curve B in the figure shows the results of Comparative Example 4, in which the hole blocking layer HBL is formed to have a resistance value of more than 30%.

FIG. 13 is a diagram showing the change in luminance over elapsed time in the display element 201.

The horizontal axis of the figure indicates the elapsed time, and the vertical axis of the figure indicates the relative luminance. The relative luminance is represented as a relative value when the luminance at an elapsed time of 0 hours is set to 1.

A curve A in the figure shows the results of Embodiment 4 (in which the hole blocking layer HBL has a resistance of 30% or less).

A curve B in the figure shows the results of Comparative Example 4 (in which the hole blocking layer HBL has a resistance value of more than 30%).

As shown in FIG. 13, it has been confirmed according to Comparative Example 4 that the lifetime is decreased as compared to Embodiment 4.

Further, the inventors prepared the display element 201 under conditions in which the resistance of the electron blocking layer EBL was made even more higher (the resistance value of the hole blocking layer HBL remained unchanged), and carried out the studies of its effects. Note that in this experiment, all organic layers, including the electron blocking layer EBL, were formed by point source deposition.

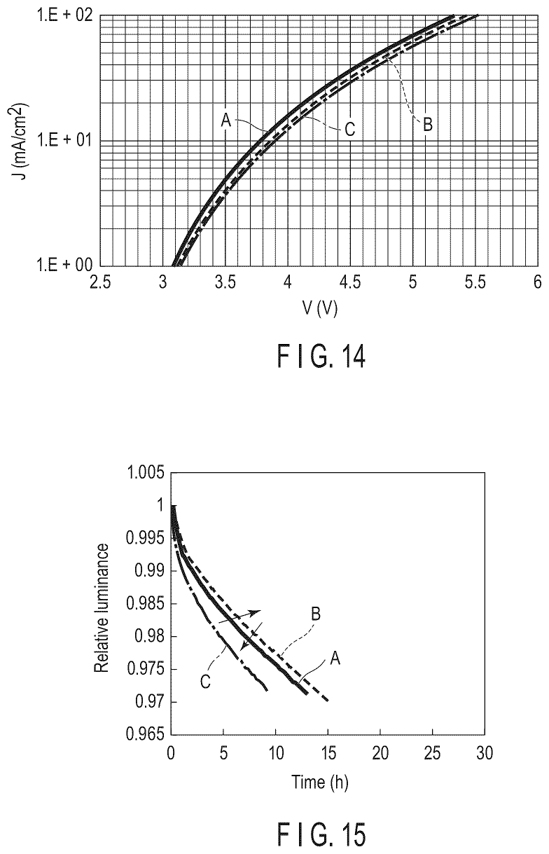

FIG. 14 is a diagram showing an example of the relationship between applied voltage and current density in the display element 201.

A curve A in the figure shows the results of Embodiment 5, in which the electron blocking layer EBL is formed so as to have a resistance R1 of 30% or less when the total resistance between the anode ΔE1 and the cathode CE is set to 100%.

A curve B in the figure shows the results of Embodiment 6, in which the electron blocking layer EBL is formed to have a resistance value R2 of 30% or less. Note here that the resistance value R2 is higher than the resistance value R1 (R1<R2).

A curve C in the figure shows the results of Comparative Example 5, in which the electron blocking layer EBL is formed to have a resistance value R3 higher than 30% (R1<R2<R3).

FIG. 15 is a diagram showing the change in luminance over elapsed time in the display element 201.

The horizontal axis of the figure indicates the elapsed time, and the vertical axis of the figure indicates the relative luminance. The relative luminance is represented as a relative value when the luminance at an elapsed time of 0 hours is set to 1.

A curve A in the figure shows the results of Embodiment 5 (in which the hole blocking layer HBL has a resistance R1).

A curve B in the figure shows the results of Embodiment 6 (in which the hole blocking layer HBL has a resistance R2).

A curve C in the figure shows the results of Comparative Example 5 (in which the hole blocking layer HBL has a resistance R3).

As shown in FIG. 15, according to Embodiment 6, which includes the hole blocking layer HBL having a resistance higher than that of Embodiment 5, the effect of improvement in lifetime was obtained as compared to Embodiment 5. On the other hand, according to Comparative Example 5, which includes the hole blocking layer HBL having a resistance having a resistance further higher than that of Embodiment 6, it has been confirmed that the lifetime was decreased as compared to those of Embodiments 4 and 5.

Based on the results of these studies, when at least one of the hole blocking layer HBL and the electron blocking layer EBL is formed to have a high resistance in the display device 201, it is preferable that it should be formed to have a resistance value of 30% or less of the total resistance in terms of obtaining the effect of improvement in lifetime.

In this embodiment, for example, the anode ΔE1 corresponds to the first anode, the organic layer OR1 corresponds to the first organic layer, the light emitting layer B-EML corresponds to the first light emitting layer, the anode ΔE2 corresponds to the second anode, the organic layer OR2 corresponds to the second organic layer, the light emitting layer G-EML corresponds to the second emitting layer, the anode ΔE3 corresponds to the third anode, the organic layer OR3 corresponds to the third organic layer, and the emitting layer R-EML corresponds to the third emitting layer.

Note that the above-provided embodiments are explained mainly in connection with the case where at least one of the hole blocking layer HBL and the electron blocking layer EBL of the blue display element 201 is formed to have a high resistance, but also as for the green display element 202 and the red display element 203, by increasing the resistance of at least one of the hole blocking layer HBL and the electron blocking layer EBL the hole blocking layer HBL, advantageous effects (including longer lifetime) similar to those described above can be obtained.

As explained above, according to this embodiment, it is possible to provide a display device with a longer lifetime and a method for manufacturing such a display device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
an anode;
a cathode opposing the anode; and
an organic layer located between the anode and the cathode, wherein
the organic layer includes a hole injection layer, a hole transport layer, an electron blocking layer, a light emitting layer, a hole blocking layer, an electron transport layer, and an electron injection layer, and
at least one of the electron blocking layer and the hole blocking layer has a resistance of 10% or more and 30% or less in a thickness direction when a total resistance between the anode and the cathode is set to 100%.

2. The display device of claim 1, wherein
ΔE2_LUMO is defined as a potential barrier between the hole blocking layer and the light emitting layer,
ΔE2_HOMO is defined as a potential barrier between the electron blocking layer and the light emitting layer,
at least one of ΔE2_LUMO and ΔE2_HOMO is 0.1 eV or higher and 0.5 eV or lower,
ΔE1_LUMO is defined as a potential barrier between the electron injection layer and the electron transport layer, and the hole blocking layer,
ΔE1_HOMO is defined as a potential barrier between the hole injection layer and the hole transport layer, and the electron blocking layer, and
at least one of ΔE1_LUMO and ΔE1_HOMO is 0.3 eV or lower.

3. The display device of claim 1, wherein
the light emitting layer is configured to emit blue light.

4. The display device of claim 1, wherein
the light emitting layer is configured to emit green light.

5. The display device of claim 1, wherein
the light emitting layer is configured to emit red light.

6. A method of manufacturing a display device, comprising:
forming an anode;
forming an organic layer on the anode; and
forming a cathode on the organic layer, wherein
the forming the organic layer includes forming a hole injection layer, forming a hole transport layer, forming an electron blocking layer, forming a light emitting layer, forming a hole blocking layer, forming an electron transport layer, and forming an electron injection layer, and
at least one of the electron blocking layer and the hole blocking layer is formed to have a resistance of 10% or more and 30% or less in a thickness direction when a total resistance between the anode and the cathode is set to 100%.

7. The method of claim 6, wherein
the organic layer is formed such that,
ΔE2_LUMO is defined as a potential barrier between the hole blocking layer and the light emitting layer,
ΔE2_HOMO is defined as a potential barrier between the electron blocking layer and the light emitting layer,
at least one of ΔE2_LUMO and ΔE2_HOMO is 0.1 eV or higher and 0.5 eV or lower,
ΔE1_LUMO is defined as a potential barrier between the electron injection layer and the electron transport layer, and the hole blocking layer,
ΔE1_HOMO is defined as a potential barrier between the hole injection layer and the hole transport layer, and the electron blocking layer, and
at least one of ΔE1_LUMO and ΔE1_HOMO is 0.3 eV or lower.

8. The method of claim 6, wherein
the light emitting layer is formed to emit blue light.

9. The method of claim 6, wherein
the light emitting layer is formed to emit green light.

10. The method of claim 6, wherein
the light emitting layer is formed to emit red light.
